(19) United States
(12) Patent Application Publication
(10) Pub. No.: US 2003/0016070 A1
(43) Pub. Date: Jan. 23, 2003

(54) Bootstrap module for multi-stage circuit

(76) Inventor: Wenhua Yang, North Andover, MA (US)

Correspondence Address: BROMBERG & SUNSTEIN LLP, 125 SUMMER STREET, BOSTON, MA, 02110-1618, US

(21) Appl. No.: 09/932,216

(22) Filed: Aug. 17, 2001

Related U.S. Application Data
(60) Provisional application No. 60/305,973, filed on Jul. 17, 2001.

(51) Int. Cl. H03K 17/16

(52) U.S. Cl. 327/390

(57) ABSTRACT

A multi-stage circuit has a first stage and a second stage that both share a bootstrap module. More specifically, the first stage has an output switch, and the second stage has an input switch in communication with the output switch. The multi-stage circuit thus includes the bootstrap module in communication with both the output switch and the input switch. The bootstrap module is capable of applying a voltage to both the input and output switches, while the applied voltage ensures that the first and second switches remain in an on state at specified times.

### PRIORITY

This application claims priority from provisional U.S. patent application No. 60/305,973, filed Jul. 17, 2001, having attorney docket number 2550/106, and entitled, “MULTI-STAGE BOOTSTRAP MODULE,” the disclosure of which is incorporated herein, in its entirety, by reference.

### FIELD OF THE INVENTION

The invention relates generally to multi-stage circuits and, more particularly, the invention relates to using bootstrap circuitry in a multi-stage circuit.

### BACKGROUND OF THE INVENTION

Bootstrap circuits have been used to ensure that a transistor (e.g., a field effect transistor that is used as a switch) remains above its turn-on voltage when such transistor is intended to be in an “on” state. U.S. Pat. No. 6,060,937 to Singer et al. and U.S. Pat. No. 6,118,325 to Singer et al. show exemplary bootstrap circuits that may be used for this purpose. The disclosures of both Singer patents hereby are incorporated herein, in their entireties, by reference.

Prior art devices have used the bootstrap circuits shown in the two Singer patents for each stage of a multi-stage circuit, such as a multi-stage switched capacitor circuit. For example, each stage in a multi-stage switched capacitor circuit may include an input switch for receiving an input signal, and an output switch coupled with the output. For each stage, prior art devices thus connect a first bootstrap circuit to the input switch, and a second bootstrap circuit to the output switch. This necessarily means that such a circuit will have two times as many bootstrap circuits as stages. In addition to using silicon real estate, use of a bootstrap circuit can create loading problems (e.g., parasitic capacitances) that necessarily are made worse when many bootstrap circuits are used. These problems are multiplied when stages have a differential configuration.

### SUMMARY OF THE INVENTION

In accordance with one aspect of the invention, a multi-stage circuit has a first stage and a second stage that both share a bootstrap module. More specifically, the first stage has an output switch, and the second stage has an input switch in communication with the output switch. The multi-stage circuit thus includes the bootstrap module in communication with both the output switch and the input switch. The bootstrap module is capable of applying a voltage to both the input and output switches, while the applied voltage ensures that the first and second switches remain in an on state at specified times.

In illustrative embodiments, the input and output switches have the same phase and duty cycles. During the specified times, the applied voltage preferably is no less than a minimum turn on voltage required to turn the first and second switches to the on state. A buffer may be coupled with the bootstrap module to reduce loading effects. The first stage and second stage may comprise a switched capacitor circuit.

The bootstrap module may be capable of receiving an input voltage at an input, and have an output to provide the above noted applied voltage. The bootstrap module also may include a complimentary switch that electrically communicates the input with the output. The bootstrap module also may include a charge storage element (e.g., a capacitor) that is capable of storing a constant voltage. The complimentary switch couples the input with the charge storage element to produce the applied voltage at the output.

In accordance with another aspect of the invention, a multi-stage switched capacitor circuit has a first stage with an output switch, a second stage having an input switch in communication with the output of the first stage, and a bootstrap module coupled between both the output and the input switch. The bootstrap module is capable of applying the same voltage to both the output and the input switch.

In some embodiments, the first stage also includes an output switch and a feedback loop coupled with the output. The voltage applied to the output may be applied to the output switch. The first stage may include a SHA, and the second stage may include an MDAC. In other embodiments, the first stage may include an MDAC, and the second stage also may include an MDAC.

In accordance with another aspect of the invention, a bootstrap module for delivering an output voltage to a switch includes an input capable of receiving an input voltage, and an output capable of delivering the output voltage. In illustrative embodiments, the output voltage is no less than a preselected voltage required to maintain the switch in an on state, and the preselected voltage is referenced to the input voltage. The bootstrap module also includes a set of input switches between the input and output. The set of input switches is capable of alternatively communicating the input voltage with the output, and the output voltage is a function of the input voltage. The set of input switches includes at least one complimentary switch.

In yet another aspect of the invention, a buffer includes an input to receive an input voltage, an output to deliver an output voltage that is substantially equal to the input voltage, and a voltage storage element. In addition, the buffer also includes a first transistor and a second transistor (the second transistor being coupled between the voltage storage element and the output), and a set of switches coupled between the first transistor and the voltage storage element. The set of switches alternate between a reset mode and an active mode. Specifically, when in the reset mode, the voltage storage element is charged to be substantially equal to the sum of the input voltage and a given voltage. Conversely, when in the active mode, the voltage storage element shifts the input voltage by the given voltage. The second transistor produces a voltage drop that is substantially equal to the given voltage.

### BRIEF DESCRIPTION OF DRAWINGS

The foregoing and advantages of the invention will be appreciated more fully from the following further description thereof with reference to the accompanying drawings wherein:

FIG. 1 schematically shows a multi-stage circuit implementing illustrative embodiments of the invention.

FIG. 2 schematically shows additional details of an exemplary multistage circuit implementing the principles shown in FIG. 1.

FIG. 3 schematically shows an illustrative buffering circuit included in the multi-stage circuit shown in FIG. 1.

FIG. 4 schematically shows a bootstrap module included in the two-stage circuit shown in FIG. 1.

### DESCRIPTION OF ILLUSTRATIVE EMBODIMENTS

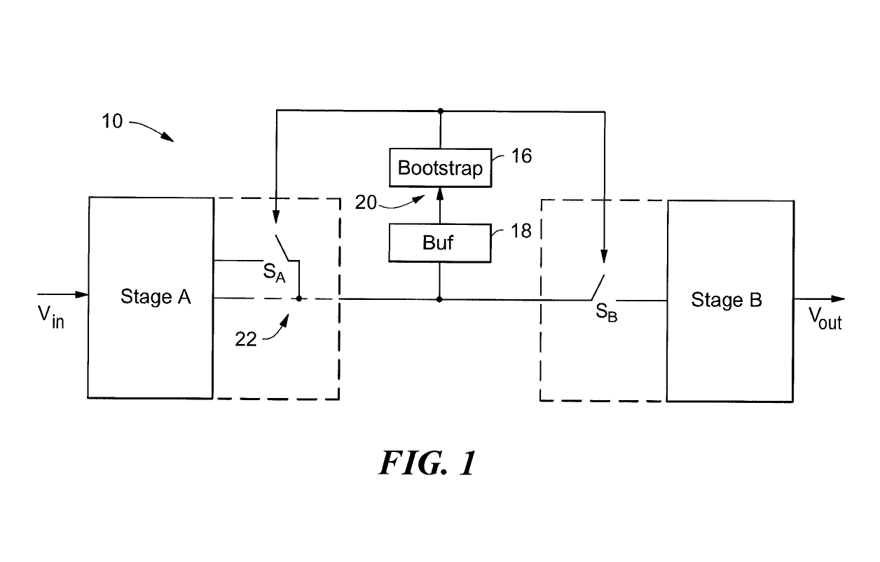

In illustrative embodiments of the invention, a multi-stage circuit includes a bootstrap circuit (referred to herein as “bootstrap module”) that is shared by two or more stages. Among other things, the bootstrap module illustratively includes complimentary switches that reduce turn-on time. In addition, the multi-stage circuit also includes a buffer between stages to reduce potential load capacitances. Details of illustrative embodiments are discussed below with reference to FIGS. 1-4.

FIG. 1 schematically shows a generic multi-stage circuit 10 that may be implemented in accordance with illustrative embodiments of the invention. In particular, the circuit 10 includes a first stage (referred to herein and shown in FIG. 1 as “stage A”), and a second stage (referred to herein and shown in FIG. 1 as “stage B”). By way of example, the circuit 10 may be a switched capacitor circuit in which the first stage is a sample-and-hold circuit (referred to in the art as a “SHA”), and the second stage is a multiplying digital to analog converter (referred to in the art as an “MDAC”). Additional stages also may be coupled, such as additional MDAC stages. Accordingly, the general function of this exemplary multi-stage circuit is to convert an analog input voltage into a digital voltage signal. For example, the circuit 10 may construct a residue signal that is used in some analog-to-digital conversion processes.

Stage A includes an output switch (identified as “switch SA”) that is coupled to an input switch (identified as “switch SB”) of stage B. In accordance with various embodiments of the invention, intervening circuitry coupled with the two switches SA and SB includes a bootstrap module 16 and a buffer 18. The bootstrap module 16 is electrically coupled with both the output switch SA and the input switch SB to ensure that they are in an “on” state when desired. In illustrative embodiments, both switches SA and SB receive the same voltage from the bootstrap module 16. Sharing the bootstrap module 16 in this manner is most effective when the switches SA and SB are in phase and have the same duty cycles.

As shown, the bootstrap module 16 includes an input 20 to receive a variable voltage signal from the output 22 of Stage A. This variable voltage signal is combined with a specified constant voltage provided by the bootstrap module 16, and applied to the switches SA and SB. The constant voltage is selected to ensure that when the circuit 10 is in an active state, the switches SA and SB also are in an “on” state. For example, if the switches SA and SB must receive a voltage of 0.7 volts to be in an “on” state, then the constant voltage is selected to ensure that such received voltage is at least 0.7 volts. In illustrative embodiments, the constant voltage is selected to maximize the gate to source voltage without putting undue stress on the switches SA and SB.

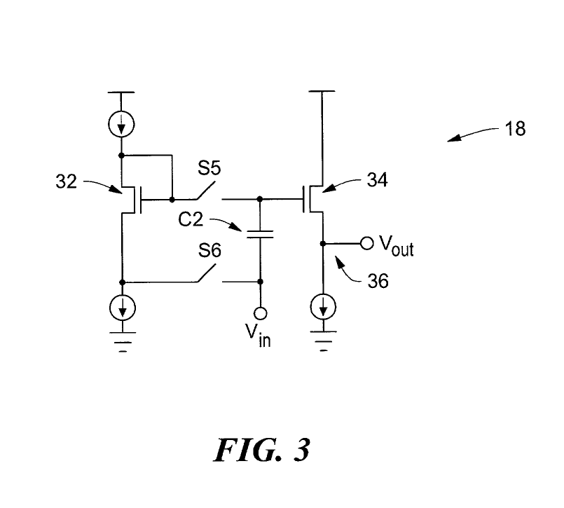

The bootstrap module 16 undesirably may produce loading problems for the multi-stage circuit 10. The buffer 18 thus is positioned and configured to substantially reduce such loading problems to acceptable levels. Details of an illustrative buffer 18 are discussed below with reference to FIG. 3.

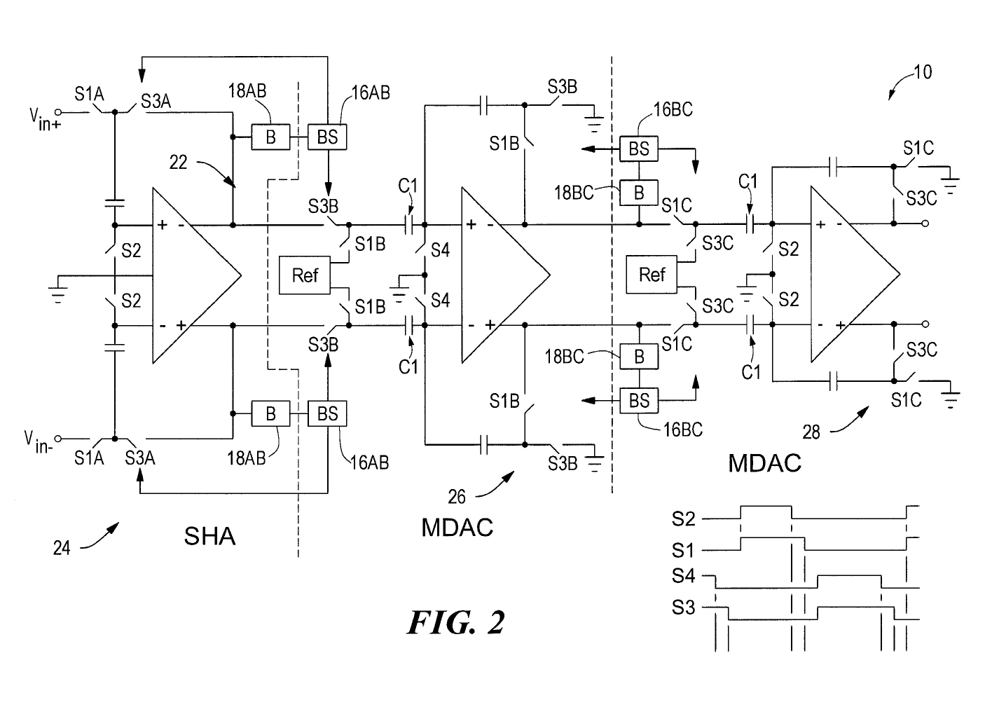

FIG. 2 schematically shows additional details of an illustrative embodiment of the multi-stage circuit 10 shown in FIG. 1. It should be noted that many of the details of the various stages are exemplary and thus, not intended to limit the scope of the invention.

The multi-stage circuit 10 shown in FIG. 2 includes a SHA 24, a first MDAC 26 and a second MDAC 28. To effectuate their function as a switched capacitor circuit, the SHA 24 and MDACs 26 and 28 include various switches and capacitors. The SHA 24 and two MDACs 26 and 28 each include differential inputs and differential outputs. It should be noted that although differential circuitry is shown, various embodiments can be implemented with circuits that do not use differential inputs and outputs.

Various switches discussed herein have an appended letter “A,” “B,” or “C.” All switches having the appended letter “A” are a part of the SHA 24, while all switches having the appended letter “B” are a part of the first MDAC 26, and all switches having the appended letter “C” are a part of the second MDAC 28. In a similar manner, elements between the SHA 24 and first MDAC 26 may have appended letters, “AB,” while elements between the first MDAC 26 and second MDAC 28 may have appended letters, “BC.”

The SHA 24 includes two inputs to receive an input analog voltage, and two corresponding output switches S3A that are coupled with its output node. I should be noted that the output switches shown herein are used in FIG. 2 as feedback switches. Notwithstanding that, such switches are referred to herein as output switches.

The first MDAC 26 includes two inputs to receive the output from the SHA 24, and a pair of input switches S3B that permit the output of the SHA 24 to be transmitted to the first MDAC input. In illustrative embodiments, all switches shown in FIG. 2 are NMOS switches. In alternative embodiments, the switches may be PMOS switches. In yet other embodiments, various combinations of different types of switches may be used, such as PMOS, NMOS and complimentary switches.

The first MDAC 26 also includes two corresponding output switches S1B. The second MDAC 28 thus includes a corresponding pair of input switches S1C that permit the output of the first MDAC 26 to be transmitted to its input.

As shown in FIG. 2, each switch identified as switch S3A is coupled with a corresponding switch S3B and corresponding first bootstrap modules 16AB. Accordingly, switches S3A preferably are operating in phase and on the same duty cycle as switches S3B. In a similar manner, each switch identified as switch S1B is coupled with a corresponding switch S1C and corresponding second bootstrap modules 16BC. Accordingly, switches S1B preferably are operating in phase and on the same duty cycle as switches S1C. To that end, the waveforms representing the duty cycles and phases of the switches are shown in FIG. 2. For example, the waveforms of all switches identified as S1 switches (i.e., S1A, S1B, and S1C) are operating according to the timing waveform identified as “S1.”

FIG. 2 also shows the various buffers 18AB and 18BC that reduce the loading effects of the bootstrap modules 16. To that end, corresponding first buffers 18AB are coupled with the first bootstrap modules 16AB, while corresponding second buffers 18BC are coupled with the second bootstrap modules 16BC.

To reduce some parasitic capacitances, it is preferred that the corresponding input and output switches be physically close to one another. For example, acceptable results should be obtained if the centers of the switches are no greater than about four hundred microns apart. Although results may be sufficient at greater distances, it is expected that performance can degrade to unacceptable levels beyond such distance.

It should be noted that a parasitic capacitance has been detected when the switches are positioned close together. In particular, when the output switches are moved physically closer to their corresponding input switches, the feedback lines of such output switches are lengthened. This lengthening of the feedback line creates the noted parasitic capacitance. This parasitic capacitance, however, has been determined to not significantly degrade system performance and thus, is acceptable within the disclosed circuit 10. Moreover, the impedance from the output of a preceding stage to the input of the next stage is significantly reduced when the switches are moved in such close proximity.

This configuration also has been determined to produce a number of other benefits. Among others, this configuration reduces the total number of components in the circuit 10 (i.e., bootstrap modules 16), consequently reducing power requirements. In addition, it has been determined that this configuration reduces the negative effects of charge injection caused by a variable impedance across switches. In particular, it is known in the art that the impedance of a switch increases as it is turned from an “on” state to an “off” state. This causes charge within the channel of the switch (assuming the switch is a transistor) to be transmitted (i.e., “injected”) away from the switch toward other elements in the circuit 10.

It also has been determined that charge injection into a specified capacitor (identified in various locations of FIG. 2 as capacitor Cl) of the circuit 10 shown in FIG. 2 should not adversely affect circuit performance when that charge injection is constant across all expected input voltages. More particularly, it is known in the art that NMOS switches, such as switches S1 and S3, have an impedance that is a function of their input voltage (without a bootstrap). Due to this fluctuating impedance (absent the respective bootstrap modules16), these switches S1 and S3 can cause a signal dependent charge (from other switches identified as switches S2 and S4, noted below) to be injected within the circuit 10 to the capacitor C1. This problem should not occur with illustrative embodiments, however, because the bootstrap module 16 causes these switches S1 and S3 to have a substantially constant impedance as a result of their constant gate to source voltage. Consequently, these switches S1 and S3 cause a substantially constant charge to be injected from switches S2 and S4. System performance thus should not be degraded.

More particularly, the first MDAC 26 also includes switches (identified “switches S4”) that connect the capacitor C1 to ground when in the on state. Those S4 switches are coupled to the input switches identified as S3B via the capacitor C1. As shown in the timing diagrams of FIG. 2, the S4 switches turn off earlier than the S3 switches. The charge from each S4 switch thus is injected both toward its corresponding capacitor C1 (i.e., in the direction of the S3B switches), and toward ground. Accordingly, as noted above, since each S3 switch has a substantially constant impedance (from the bootstrap module 16), it desirably causes a substantially constant charge to be injected toward its corresponding capacitor. In other words, since they are coupled with one of the bootstrap modules 16, each S3 switch has an impedance that is not a function of a fluctuating input voltage signal.

The other bootstrap modules 16 in the circuit 10 also provide the same benefits. The S4 and S3 switches thus were discussed by way of example and no intended to suggest that the other bootstrap modules 16 do not provide the same results.

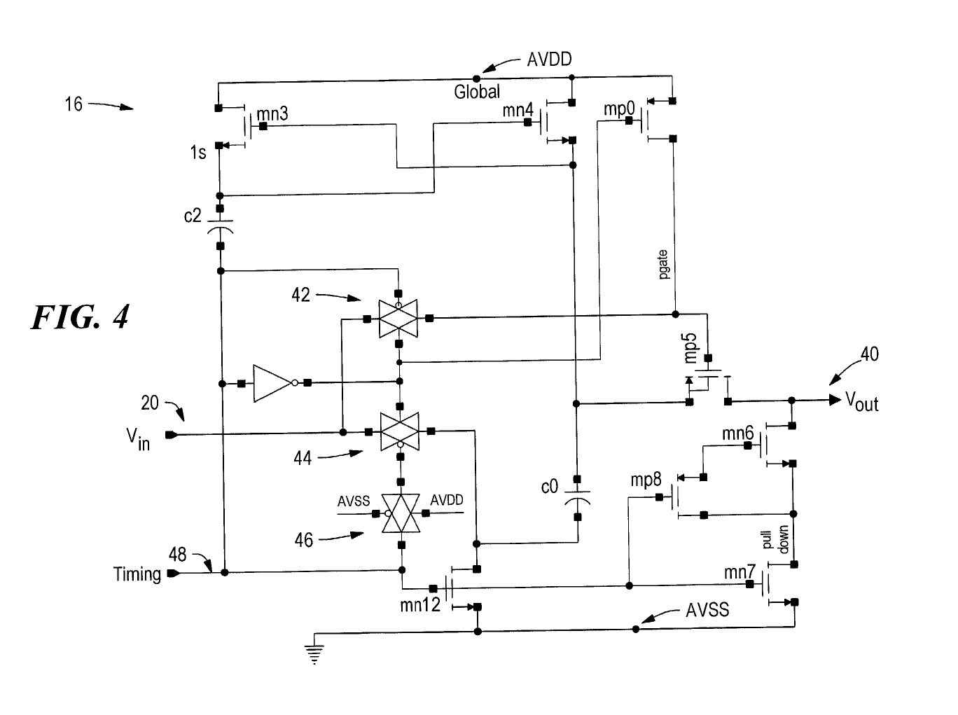

In some embodiments, the bootstrap module 16 and buffer 18 may be similar to those disclosed in the above noted Singer patents. In other embodiments, the buffer 18 and bootstrap module 16 respectively are configured as shown in FIGS. 3 and 4, discussed below. Specifically, FIG. 3 shows a buffer 18 that may be used with illustrative embodiments of the invention. Qualitatively, the buffer 18 produces an output voltage that tracks its input voltage. To that end, the buffer 18 includes a pair of switches S5 and S6 that cooperate to charge an internal capacitor C2 during a specified time interval. In addition, the buffer 18 also includes a first MOSFET 32 having its gate and drain tied, and a second MOSFET 34 coupled with the output. Various current sources also may be included to maintain the MOSFETS in an active mode.

The buffer 18 operates in two modes. In particular, the buffer 18 operates in a reset mode, in which it charges the internal capacitor C2 to a voltage so that the output has a voltage substantially equal to the input voltage, and an active mode, in which it delivers the output voltage to its output. When in the reset mode, the switches S5 and S6 are in an on state, thus charging the capacitor to the gate to source voltage of the first MOSFET 32. When in the active mode, the switches S5 and S6 are in an off state. Therefore, the output voltage equals the input voltage, plus the gate to source voltage of the first MOSFET 32, less the gate to source voltage of the second MOSFET 34. It should be noted that when the buffer 18 is between the SHA 24 and first MDAC 26 (i.e., the buffer 18AB), the switches S5 and S6 have the same timing as the S1 switches. When the buffer 18 is between the first and second MAC 26 and 28 (i.e., the buffer 18BC), however, the switches S5 and S6 have the same timing as the S3 switches.

FIG. 4 schematically shows a bootstrap module 16 configured in accordance with illustrative embodiments of the invention. In summary, the bootstrap module 16 includes an input 38 to receive the input voltage signal, a capacitor Co to store the constant bootstrap voltage, and an output 40 to deliver the output voltage. As noted above, the output voltage should be equal to the sum of the input voltage and a constant voltage. In illustrative embodiments, the constant voltage is the high rail voltage Vdd.

The bootstrap module 16 also includes a plurality of circuit elements to provide the desired function. Among those elements are first and second complimentary switches 42 and 44 that couple the input voltage to the output 40, and various transistors. A third complimentary switch 46, which is on in all modes (noted below), also is included. The bootstrap module 16 is powered by the noted high rail voltage Vdd at a node AVDD, and has a ground at node AVSS. It should be noted that the complimentary switches 42, 44, and 46 are included since they provide more rapid turn-on times than those switches used in prior art bootstrap modules. Accordingly, the bootstrap module 16 should be more responsive than prior art bootstrap modules.

The bootstrap module 16 operates in a charging mode, in which the output voltage is at ground, and in a bootstrap mode, in which the output voltage is equal to the sum of the input voltage and the voltage Vdd. When in the charging mode, the first and second complimentary switches 42 and 44 are in an off state, thus preventing the input voltage from begin transmitted into the circuit. In addition, transistors MN6 and MN7 are on to connect the output 40 to ground, transistor MN12 is on to connect one plate of the capacitor CO to ground, and transistor MN 4 is on to connect the other plate of the capacitor CO to Vdd. Consequently, the capacitor CO charges up to a voltage equal to Vdd.

The bootstrap module 16 transitions to the bootstrap mode after receipt of the falling edge of a timing clock pulse via a timing input 48. More particularly, a high signal received by the timing input 48 causes the bootstrap module 16 to be in the charging mode, while a low signal received by the timing input 48 causes the bootstrap module 16 to be in the bootstrap mode. Accordingly, after the bootstrap module 16 transitions to the bootstrap mode, first and second complimentary switches 42 and 44 turn on. Consequently, the transistor MP 5 turns on (via the first complimentary switch 42), and the input voltage is transmitted to the capacitor via the second complimentary switch 44. Specifically, since transistor MP 5 is turned on by the first switch, the output voltage has a voltage equal to the capacitor voltage (i.e., Vdd) plus the input voltage.

The parameters for the circuit elements may be selected based upon the application to be implemented. For example, transistor MP 5 is shown as having a gate width of 100 microns, and a gate length of about 0.35 microns in some applications. These specifications are given by way of example and thus, are not intended to limit the scope of various embodiments of the invention.

Although various exemplary embodiments of the invention are disclosed below, it should be apparent to those skilled in the art that various changes and modifications can be made that will achieve some of the advantages of the invention without departing from the true scope of the invention. These and other obvious modifications are intended to be covered by the described invention and appended claims.

What is claimed is:

1. A multi-stage circuit having a first stage and a second stage, the first stage having an output switch, the second stage having an input switch in communication with the output switch, the multi-stage circuit comprising:
a bootstrap module in communication with both the output switch and the input switch, the bootstrap module being capable of applying a voltage to both the input and output switches, the applied voltage ensuring that the first and second switches remain in an on state at specified times.

2. The multi-stage circuit as defined by claim 1 wherein the input and output switches have the same phase and duty cycles.

3. The multi-stage circuit as defined by claim 1 wherein during the specified times, the applied voltage is no less than a minimum turn on voltage required to turn the first and second switches to the on state.

4. The multi-stage circuit as defined by claim 1 wherein the bootstrap module is capable of receiving an input voltage at an input, the bootstrap module having an output to provide the applied voltage, the bootstrap module including a complimentary switch that electrically communicates the input with the output.

5. The multi-stage circuit as defined by claim 4 wherein the bootstrap module includes a charge storage element, the charge storage element being capable of storing a constant voltage, the complimentary switch coupling the input with the charge storage element to produce the applied voltage at the output.

6. The multi-stage circuit as defined by claim 1 further including:
a buffer coupled with the bootstrap module.

7. The multi-stage circuit as defined by claim 1 wherein the first stage and second stage comprise a switched capacitor circuit.

8. A multi-stage switched capacitor circuit comprising:
a first stage having an output switch;
a second stage having an input switch in communication with the output switch of the first stage; and
a bootstrap module coupled between both the output switch and the input switch, the bootstrap module being capable of applying the same voltage to both the output switch and the input switch.

9. The multi-stage switched capacitor circuit as defined by claim 8 wherein the first stage also includes a feedback loop coupled with the output switch.

10. The circuit as defined by claim 9 wherein the output switch and the input switch operate with the same phase and duty cycle.

11. The circuit as defined by claim 8 further including a buffer coupled between the bootstrap module and the output switch.

12. The circuit as defined by claim 8 wherein the bootstrap module is capable of receiving an input voltage at an input, the bootstrap module having a bootstrap output to provide the applied voltage, the bootstrap module including a complimentary switch that is capable of electrically communicating the input with the bootstrap output.

13. The circuit as defined by claim 8 wherein the voltage applied to the input switch is no less than a minimum turn on voltage required to turn the input switch to the on state.

14. The circuit as defined by claim 8 wherein the wherein the first stage includes a SHA, and the second stage includes an MDAC.

15. A multi-stage switched capacitor circuit comprising:
a first stage having an output feedback loop;
a second stage having an input switch in communication with the output feedback loop of the first stage; and
means for applying a bootstrap voltage to the output feedback loop and the input switch, the bootstrap voltage maintaining the input switch in an on state during a specified time interval.

16. The circuit as defined by claim 15 wherein the applying means is coupled between the output feedback loop and the input switch.

17. The multi-stage switched capacitor circuit as defined by claim 15 wherein the output feedback loop includes an output switch, the voltage applied to the output feedback loop being applied to the output switch.

18. The circuit as defined by claim 17 wherein the output switch and the input switch operate with the same phase and duty cycle.

19. The circuit as defined by claim 15 wherein the applying means is capable of receiving an input voltage at an input, the applying means having an output to provide the applied voltage, the applying means including means for electrically communicating the input with the output.

20. The circuit as defined by claim 15 wherein the wherein the first stage includes a SHA, and the second stage includes an MDAC.

21. A bootstrap module for delivering an output voltage to a switch, the bootstrap module comprising:
an input capable of receiving an input voltage;
an output capable of delivering the output voltage, the output voltage being no less than a preselected voltage required to maintain the switch in an on state, the preselected voltage being referenced to the input voltage; and
a set of input switches between the input and output, the set of input switches being capable of alternatively communicating the input voltage with the output, the output voltage being a function of the input voltage,
the set of input switches including at least one complimentary switch.

22. The bootstrap module as defined by claim 21 further comprising a charge storage element for storing the preselected voltage, the charge storage element being in electrical communication with the set of input switches.

23. The bootstrap module as defined by claim 21 wherein the output voltage is a function of the input voltage.

24. A buffer comprising:
an input to receive an input voltage;
an output to deliver an output voltage, the output voltage being substantially equal to the input voltage;
a voltage storage element;
a first transistor and a second transistor, the second transistor coupled between the voltage storage element and the output;
a set of switches coupled between the first transistor and the voltage storage element, the set of switches alternating between a reset mode and an active mode,
when in the reset mode, the voltage storage element being charged to be substantially equal to the sum of the input voltage and a given voltage,
when in the active mode, the voltage storage element shifting the input voltage by the given voltage,
the second transistor producing a voltage drop that is substantially equal to the given voltage.

25. The buffer as defined by claim 24 wherein the first transistor is a field effect transistor having its drain node and gate node connected.

26. The buffer as defined by claim 24 wherein the second transistor is a field effect transistor, the output being coupled with the source node of the second transistor.

27. The buffer as defined by claim 24 wherein the given voltage is a negative value and the voltage drop of the second transistor is a negative voltage drop.

28. The buffer as defined by claim 24 wherein the given voltage is derived from the first transistor.
